(19) United States
(12) Patent Application Publication
(10) Pub. No.: US 2025/0253811 A1
(43) Pub. Date: Aug. 7, 2025

(54) VOLTAGE LIMITING CIRCUIT AND METHOD FOR A POWER AMPLIFIER

(71) Applicant: SKWORKS SOLUTIONS, INC., Irvine, CA (US)

(72) Inventors: Anthony Francis Quaglietta, Methuen, MA (US); Joseph A. Cuggino, Westford, MA (US)

(21) Appl. No.: 19/039,874

(22) Filed: Jan. 29, 2025

Related U.S. Application Data
(60) Provisional application No. 63/549,065, filed on Feb. 2, 2024.

(51) Int. Cl. H03F 1/52; H03F 3/24

(52) U.S. Cl. CPC H03F 1/52; H03F 3/245; H03F 2200/435; H03F 2200/444; H03F 2200/451

(57) ABSTRACT

A voltage limiting circuit for a power amplifier that includes a diode circuit, a bias circuit to generate a bias voltage, and a sink circuit. The diode circuit is coupled to an output of an amplification stage of the power amplifier and configured to provide a conductive path from the output when an output voltage of the amplification stage exceeds a predetermined threshold. The sink circuit includes an attenuator, coupled to the diode circuit and the bias circuit, and is configured to reduce the bias voltage when the output voltage exceeds the predetermined threshold to thereby limit the output voltage, and the attenuator is configured to reduce a feedback of the output voltage routing through the sink circuit.

### CROSS-REFERENCE TO RELATED APPLICATIONS

This application claims priority under 35 U.S.C. § 119 (e) to U.S. Provisional Patent Application 63/549,065 titled VOLTAGE LIMITING CIRCUIT AND METHOD FOR A POWER AMPLIFIER, filed on Feb. 2, 2024, and hereby incorporated by reference in its entirety for all purposes.

### BACKGROUND

### Technical Field

The present disclosure generally relates to power amplifiers (PAS) for radio-frequency (RF) applications.

### Description of Related Technology

In radio-frequency (RF) applications, an RF signal to be transmitted is typically generated by a transceiver. Such an RF signal can then be amplified by a power amplifier (PA), and the amplified RF signal can be routed to an antenna for transmission.

### SUMMARY

The innovations described in the claims each have several aspects, no single one of which is solely responsible for its desirable attributes. Without limiting the scope of the claims, some prominent features of this disclosure will now be briefly described.

In a first aspect, a voltage limiting circuit for a power amplifier (PA) is disclosed. The voltage limiting circuit comprises a diode circuit coupled to an output of an amplification stage. The diode circuit is configured to provide a conductive path from the output when an output voltage exceeds a predetermined threshold. The voltage limiting circuit further comprises a sink circuit coupled to the diode circuit and a bias circuit. The sink circuit is configured to reduce a bias voltage provided by the bias circuit when the output voltage exceeds the predetermined threshold to thereby limit the output voltage. The sink circuit comprises an attenuator, the attenuator configured to reduce a feedback of the output voltage or RF signal, respectively, routing through the sink circuit.

In some embodiments, the attenuator can be configured to filter the output voltage.

In some embodiments, the attenuator can include a broadband filter.

In some embodiments, the attenuator can be configured as a high pass filter or a low pass filter.

In some embodiments, the voltage limiting circuit can further comprise a reverse diode configured to protect the voltage limiting circuit against a negative voltage swing, the reverse diode being coupled in parallel to the diode circuit. In particular, the reverse diode can be at least one reverse diode, preferably two reverse diodes depending on the power level of the RF signal.

In some embodiments, the sink circuit can further comprise an isolation resistor in series with the attenuator, the isolation resistor being configured to isolate from the bias circuit when the output voltage exceeds the predetermined threshold. That means the isolation resistor can be used when the output voltage exceeds the predetermined threshold and the voltage limiting circuit is active or ON, respectively.

In some embodiments, the isolation resistor is coupled to the bias circuit and the attenuator.

In a second aspect, a power amplifier (PA) is disclosed. The power amplifier comprises an input port configured to receive an input radio-frequency (RF) signal and an output port configured to yield an amplified RF signal. The power amplifier also comprises one or more amplification stages implemented between the input port and the output port. The one or more amplification stages are configured to amplify the input RF signal to yield the amplified RF signal. Further, the power amplifier comprises a bias circuit for each of the one or more amplification stages; and a ruggedness protection circuit including a diode circuit coupled to an output of a selected one of the one or more amplification stages. The diode circuit is configured to provide a conductive path from the output when an output voltage exceeds a predetermined threshold. The ruggedness protection circuit further includes a sink circuit coupled to the diode circuit and a selected bias circuit, the sink circuit configured to reduce a bias voltage provided by the selected bias circuit when the output voltage exceeds the predetermined threshold to thereby limit the output voltage. The sink circuit comprises an attenuator which is configured to reduce a feedback of the output voltage or RF signal, respectively, routing through the sink circuit.

In some embodiments, the one or more amplification stages includes a driver stage and an output stage.

In some embodiments, the selected amplification stage is the output stage.

In some embodiments, the selected bias circuit corresponds to the output stage.

In some embodiments, the selected bias circuit corresponds to the driver stage.

In some embodiments, the ruggedness protection circuit is configured to limit the output voltage to reduce likelihood of damage to the output stage without significantly reducing performance of the PA.

In a third aspect, a wireless device is disclosed. The wireless device comprises a transceiver configured to generate a radio-frequency (RF) signal, and an RF module in communication with the transceiver. The RF module includes a power amplifier (PA). The PA includes one or more amplification stages configured to amplify the RF signal. The PA further includes a bias circuit for each of the one or more amplification stages. The PA further includes a ruggedness protection circuit including a diode circuit coupled to an output of a selected one of the one or more amplification stages, the diode circuit being configured to provide a conductive path from the output when an output voltage exceeds a predetermined threshold. The ruggedness protection circuit further includes a sink circuit coupled to the diode circuit and a selected bias circuit. The sink circuit is configured to reduce a bias voltage provided by the selected bias circuit when the output voltage exceeds the predetermined threshold to thereby limit the output voltage. The sink circuit comprises an attenuator, which is configured to reduce a feedback of the output voltage routing through the sink circuit. The wireless device also comprises an antenna in communication with the RF module, the antenna configured to facilitate transmission of the amplified RF signal.

In a fourth aspect, a method for operating a power amplifier (PA) is disclosed. The method includes detecting a condition where an output voltage of an amplification stage exceeds a predetermined threshold. The method also includes providing a conductive path from an output of the amplification stage upon detecting of the condition. The method further includes activating a sink circuit coupled to the conductive path to reduce a bias voltage provided by a bias circuit. Further, the method includes reducing a feedback of the output voltage routing through the sink circuit.

In some embodiments, the feedback of the output voltage is reduced by an attenuator included in the sink circuit.

For purposes of summarizing the disclosure, certain aspects, advantages and novel features of the innovations have been described herein. It is to be understood that not necessarily all such advantages may be achieved in accordance with any particular embodiment. Thus, the innovations may be embodied or carried out in a manner that achieves or optimizes one advantage or group of advantages as taught herein without necessarily achieving other advantages as may be taught or suggested herein.

### BRIEF DESCRIPTION OF THE DRAWINGS

FIG. 1 depicts a power amplifier (PA) having one or more amplification stages configured to receive an input signal and amplify it to generate an amplified signal, according to one embodiment of the present disclosure.

FIGS. 2A and 2B show examples of a peak voltage limiting (PVL) circuit implemented for a PA system having three amplification stages, according to one embodiment of the present disclosure.

FIG. 3 shows an example of a PA system having three amplification stages, but without a ruggedness protection circuit, according to one embodiment of the present disclosure.

FIG. 4 shows an example of a ruggedness protection circuit implemented in the context of the example PA system of FIG. 3, according to one embodiment of the present disclosure.

FIG. 5 shows that in some embodiments, a PVL circuit can include a group of one or more diodes arranged in series that couples a collector of the amplifying transistor to a transistor that can be activated to provide sinking of base current of the amplifying transistor.

FIG. 6 shows a more specific example of the peak voltage detection configuration of FIG. 5, where peak voltage is detected at the collector of the last stage and such voltage is routed to a sinking transistor, according to one embodiment of the present disclosure.

FIG. 7 shows another more specific example of the peak voltage detection configuration of FIG. 5, where peak voltage is detected at the collector of the last stage and such voltage is routed to a sinking transistor so as to reduce the base voltage of the same third stage, according to one embodiment of the present disclosure.

FIGS. 8-11 show examples where PVL circuits are implemented in different manners in an example 3-stage PA system, according to various embodiments of the present disclosure.

FIG. 12 shows an example of how a collector voltage Vcc3 can be advantageously limited by a PVL circuit having one or more features as described herein, according to one embodiment of the present disclosure.

FIG. 13A shows a stability plot with a PVL circuit at a frequency of 5955 MHz, according to one embodiment of the present disclosure.

FIG. 13B particularly shows a stability plot with a PVL circuit at a frequency of 6535 MHz, according to one embodiment of the present disclosure.

FIG. 13C shows a stability plot with a PVL circuit at a frequency of 7095 MHz, according to one embodiment of the present disclosure.

FIG. 14A shows EVM performance plots without a PVL circuit, according to one embodiment.

FIG. 14B shows EVM performance plots with a PVL circuit, according to one embodiment.

FIG. 15A shows gain profiles without a PVL circuit, according to one embodiment of the present disclosure.

FIG. 15B shows gain profiles with a PVL circuit, according to one embodiment of the present disclosure.

FIG. 16 depicts a die 200 that can include a PVL circuit 104 having one or more features as described herein, according to one embodiment of the present disclosure.

FIG. 17 schematically depicts an example module having a packaging substrate that is configured to receive a plurality of components, according to one embodiment of the present disclosure.

FIG. 18 schematically depicts an example wireless device 400 having one or more advantageous features described herein, according to one embodiment of the present disclosure.

### DETAILED DESCRIPTION

The following detailed description of certain embodiments presents various description of specific embodiments. However, the innovation described herein can be embodied in a multiple of different ways, for example, as defined and covered by the claims. In this description, reference is made to the drawings where like reference numbers can indicate identical or functionally similar elements. It will be understood that elements illustrated in the figures are not necessarily drawn to scale. Moreover, it will be understood that certain embodiments can include more elements than illustrated in a drawing and/or in a subset of the elements illustrated in a drawing. Further, some embodiments can incorporate any suitable combination of features from two or more drawings.

In some radio-frequency (RF) applications, amplifiers such as power amplifiers (PAS) are typically designed to function under normal operating conditions, and also survive under at least some abnormal conditions. Such survivability under abnormal operating conditions is typically referred to as ruggedness of the amplifier.

In many RF applications, survivability of amplifiers with voltage standing wave ratio (VSWR) of up to 10:1 and over temperature range extremes is typically expected. Amplifiers can be destroyed or damaged when producing large RF voltage swings. Such voltage swings can be maximized or enhanced at certain load phases and elevated VSWR conditions, as well as in the presence of a high level of input incident RF power level. Voltage maxima or peak produced under such extreme conditions can induce an avalanche current due to, for example, collector-base voltage (Vcb) breakdown in NPN devices. With such a breakdown, a device can be destroyed or suffer non-recoverable damage.

In some situations, ruggedness of an amplifier can be an issue when the amplifier is operated outside of its intended range. For example, an amplifier can be designed to operate at a supply voltage (Vcc) of 3.6V, with possible operation at a maximum design limit of 4.6V. When such an amplifier is operated at 5V, its survival can be marginal even at room temperature. For example, such an amplifier can fail at room temperature from input power (Pin) range of −5 dBm to +5 dBm for a VSWR of 6:1. It is noted that such failures typically occur at a phase closer to voltage peaking rather than current peaking.

In some implementations, the present disclosure relates to a peak voltage limiting (PVL) circuit that can be implemented in an amplifier such as a power amplifier (PA). Although various examples are described in the context of PAs, it will be understood that one or more features of the present disclosure can also be implemented in other types of RF amplifiers.

FIG. 1 depicts a power amplifier (PA) 100 having one or more amplification stages 102 configured to receive an input signal RF_IN and amplify it to generate an amplified signal RF_OUT, according to one embodiment of the present disclosure. Such a PA can include and/or be functionally coupled with a peak voltage limiting (PVL) circuit 104. Examples of such a PVL circuit are described herein in greater detail.

In some embodiments, and as described herein, a PVL circuit can be implemented as a closed loop system configured to a respond to a peak voltage condition at the output of an amplifier stage (e.g., output stage) to reduce the bias provided to that amplifier stage (e.g., output stage) by another stage (e.g., driver stage). With such a closed loop system, the gain of the output stage amplification can be adjusted to, for example, reduce the obtainable maximum voltage and thereby avoid damage to the output stage. As described herein, such a closed loop system can be configured to provide improved ruggedness functionality while having minimal or no effect on normal operating characteristics of the amplifier. In the context of bipolar junction transistors (BJTs), the foregoing reduced bias can be a reduced base current. Although some examples are described herein in the context of such BJTs, it will be understood that one or more features of the present disclosure can also be implemented with other types of amplifying transistors.

In some embodiments, one or more features of the present disclosure can be implemented in PAs utilizing a number of process technologies. For example, PAs based on silicon germanium (SiGe), gallium arsenide (GaAs), silicon-on-insulator (SOI), or any other semiconductor process can benefit from one or more features as described herein.

FIGS. 2A and 2B show examples of a PVL circuit 104 implemented for a PA system 100 having three amplification stages 102a to 102c, according to one embodiment of the present disclosure. An input signal RF_IN is shown to be provided to an input of the first stage 102a, and an output of the first stage 102a is shown to be provided to an input of the second stage 102b. Similarly, an output of the second stage 102b is shown to be provided to an input of the third stage 102c. An output of the third stage 102c is shown to yield an output RF_OUT of the RF system 100. Each of the three stages is shown to be coupled to a DC supply circuit (110a, 110b or 110c) and a bias circuit (112a, 112b or 112 c).

In the example of FIG. 2A, the PVL circuit 104 can include a detection circuit 120 that couples the output of the last stage 102c (e.g., the third stage in the three-stage example) with the bias circuit 112c for the same stage. In the example of FIG. 2B, the PVL circuit 104 can include a detection circuit 120 that couples the output of the last stage 102c (e.g., the third stage in the three-stage example) with the bias circuit 112b for another stage (e.g., stage 102b). Examples of the two configurations are described herein in greater detail. It will be understood that other configurations can also be implemented. It will also be understood that although various examples are described herein in the context of three-stage PA systems, one or more features of the present disclosure can also be implemented in PA systems having different numbers of stages.

FIG. 3 shows an example of a PA system having three amplification stages, but without a ruggedness protection circuit, according to one embodiment of the present disclosure. The three amplification stages are shown to be provided by amplifying transistors Q1, Q2 and Q3 (e.g., NPN bipolar junction transistors (BJTs)). More particularly, an input RF signal RF_IN is shown to be provided to the base of Q1 through a matching network which can include, for example, L1 and C1 in series. The output of Q1 is shown to be provided through the collector, to the base of Q2 through a matching network which can include, for example, L2 and C2 in series. Similarly, the output of Q2 is shown to be provided through the collector, to the base of Q3 through a matching network which can include, for example, L3 and C3 in series. The output of Q3 is shown to be provided through the collector, to the PA output (as RF_OUT) through an output matching network 146. Such an output matching network can include, for example, L4, L5 and C6 in series, and C4 and C5 coupling respective nodes 142, 144 to ground.

In the example of FIG. 3, each of Q1, Q2 and Q3 is shown to be provided with a supply voltage through the collector. More particularly, the collector node 132 of Q1 is shown to receive a supply voltage Vcc1 through a line element such as a choke inductance L7. The input node for the supply voltage Vcc1 is shown to be coupled to ground through C7. For the purpose of description, such a circuit for providing Vcc1 to the collector node 132 can be identified as 110a. Similarly, the collector node 136 of Q2 is shown to receive a supply voltage Vcc2 through a line element such as a choke inductance L8. The input node for the supply voltage Vcc2 is shown to be coupled to ground through C8. For the purpose of description, such a circuit for providing Vcc2 to the collector node 136 can be identified as 110b. Similarly, the collector node 140 of Q3 is shown to receive a supply voltage Vcc3 through a line element such as a choke inductance L9. The input node for the supply voltage Vcc3 is shown to be coupled to ground through C9. For the purpose of description, such a circuit for providing Vcc3 to the collector node 140 can be identified as 110c. It will be understood that the supply voltage circuits 110a to 110c are examples, and that supply voltages can be provided to the amplification transistors in other configurations.

In the example of FIG. 3, each of Q1, Q2 and Q3 is shown to be provided with a base voltage at the base in an emitter-follower configuration. More particularly, the base node 130 of Q1 is shown to receive a bias signal from a bias circuit 112a so as to yield a base voltage Vbb1. The bias circuit 112a is shown to include transistor Q4, with a reference voltage Vref1 being input into the base and the output of Q4 being provided through the emitter, and with Vbat1 supply voltage being provided to the collector. The output of Q4 is shown to be coupled to the base node 130 through a line element such as an inductance L11. Similarly, the base node 134 of Q2 is shown to receive a bias signal from a bias circuit 112b so as to yield a base voltage Vbb2. The bias circuit 112b is shown to include transistor Q5, with a reference voltage Vref2 being input into the base and the output of Q5 being provided through the emitter, and with Vbat2 supply voltage being provided to the collector. The output of Q5 is shown to be coupled to the base node 134 through a line element such as an inductance L12. Similarly, the base node 138 of Q3 is shown to receive a bias signal from a bias circuit 112c so as to yield a base voltage Vbb3. The bias circuit 112c is shown to include transistor Q6, with a reference voltage Vref3 being input into the base and the output of Q6 being provided through the emitter, and with Vbat3 supply voltage being provided to the collector. The output of Q6 is shown to be coupled to the base node 138 through a line element such as an inductance L13. In the example of FIG. 3, each of the inductances L11, L12, L13 can be configured to provide, for example, isolating functionality to isolate the corresponding bias circuit from the RF signal passing through the corresponding stage of amplification.

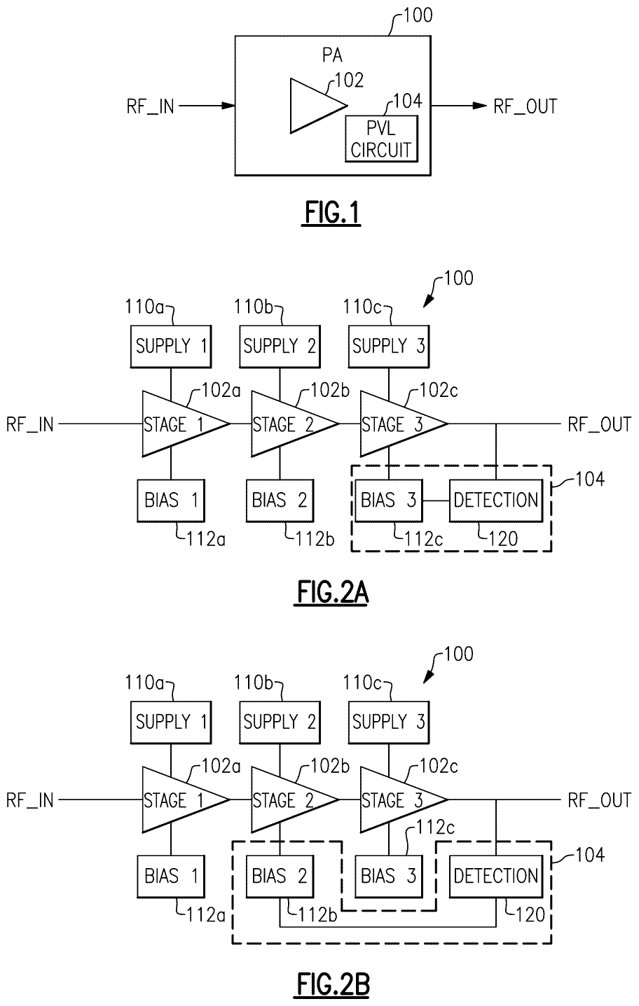

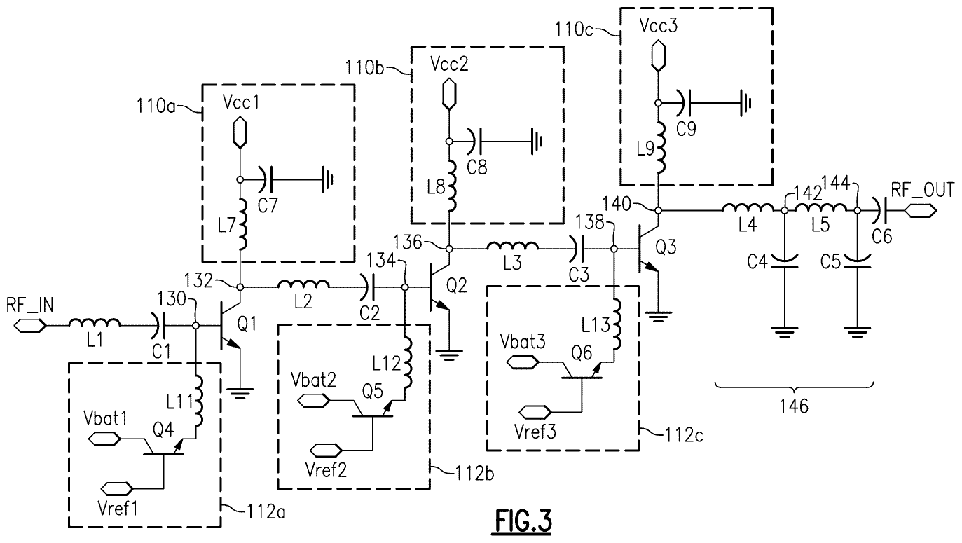

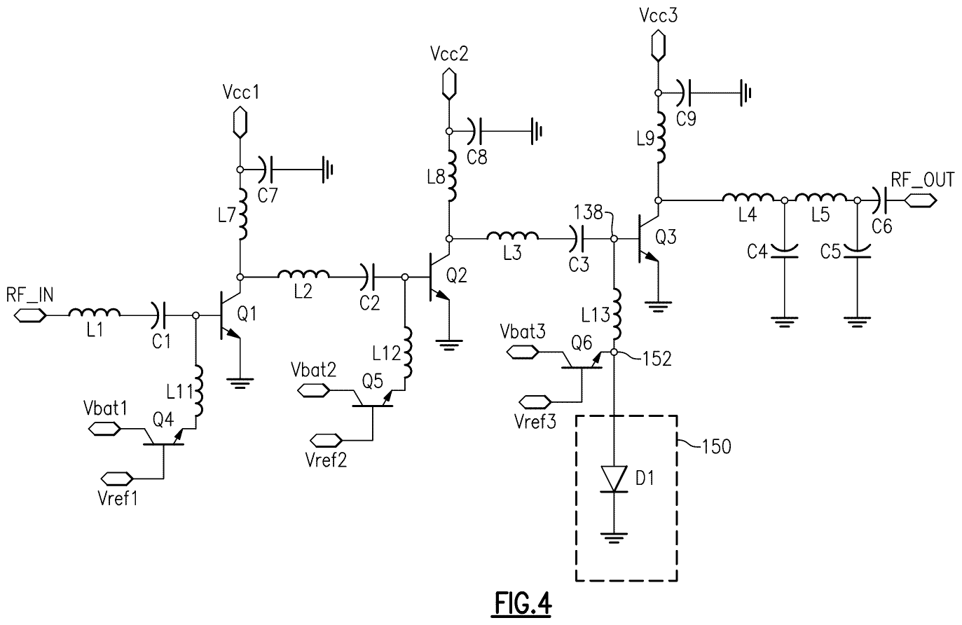

FIG. 4 shows an example of a ruggedness protection circuit 150 implemented in the context of the example PA system of FIG. 3, according to one embodiment of the present disclosure. The ruggedness protection circuit 150 is shown to include a diode D1 that couples node 152 to ground. The node 152 is coupled to the base node 138 of Q3, and accordingly, the diode coupling to ground can provide current sink functionality in which the diode D1 starts to conduct current away from the base to thereby prevent the current participating in or having a multiplicative avalanche effect within Q3 when the collector node of Q3 experiences a high voltage such as a peak voltage excursion event in Q3. Furthermore, the ruggedness protection circuit 150 provides an attenuating functionality configured to reduce a feedback of the RF signal routing through node 152 to ground. It is noted, however, that such a ruggedness protection circuit typically leads to a trade-off with normal operating performance parameters such as power-added efficiency (PAE) and/or error vector magnitude (EVM).

In some implementations, the present disclosure relates to a peak voltage limiting (PVL) circuit that can provide effective ruggedness protection functionality while having little or no effect on normal operating performance. As described herein, such a PVL circuit can be configured to detect a condition where a peak voltage at a collector of an amplifying transistor (e.g., of an output stage) exceeds some predetermined threshold. When such a condition is detected, the PVL circuit can reduce the base voltage Vbb of an amplifying transistor by activating a sink for the base current. As described herein, such an amplifying transistor for which Vbb is reduced may or may not be the same amplifying transistor at which the exceeding peak voltage condition is detected. For example, in the context of a 3-stage configuration, the exceeding peak voltage condition can be detected at the collector of the last stage (stage 3), and the stage for which Vbb is reduced in response can be stage 3 or another stage such as stage 2.

FIG. 5 shows that in some embodiments, the foregoing PVL circuit can include a group of one or more diodes arranged in series (indicated as 160) that couples a collector of the amplifying transistor (for which exceeding peak voltage condition is being detected) to a transistor that can be activated to provide sinking of base current of the amplifying transistor (for which Vbb is being reduced). Such a reduction in Vbb results in reduction of gain and drive power capability of the amplifying transistor, to thereby reduce the peak voltage at the collector as a result of a smaller RF signal on that node.

In FIG. 5, the peak voltage being detected is indicated as Vc, and the transistor for sinking of the base current (sometimes referred as a sinking transistor) is shown to have its base coupled to the output of the group of N diode(s) 160 (where N is a positive integer). The sinking transistor is shown to have its collector coupled to an attenuator 122. The attenuator is coupled to a node representative of the base voltage (Vbb) being reduced. The emitter of the sinking transistor is coupled to ground. The attenuator is configured to reduce a feedback signal of the base voltage (Vbb) passing through the output of the group of N diode(s) 160. Furthermore, the attenuator can be configured to filter the base voltage.

In FIG. 5, a resistance R is shown to be provided in series with the group of N diode(s) 160. The resistance R is configured for the PVL circuit in a situation when the peak voltage does not exceed the predetermined threshold, so the PVL functionality being inactive or the diodes 160 are turned OFF, respectively. In some embodiments, one or more circuit elements such as an inductance can replace the resistance R, or be implemented with the resistance R. In some embodiments, the number of diodes (N), R, and/or other circuit element(s) can be selected to, for example, set the selected voltage to facilitate the foregoing Vbb-reduction functionality. In some embodiments, such a selected voltage can be based on, for example, a conduction onset voltage associated with the group of N diode(s) 160. Such a conduction onset voltage can be based on the degree and exponential rise in current conducted through the diode(s) as voltage builds on the collector node. In some embodiments, such an exponential nature of the diode curve can be utilized to provide a clamping effect on the voltage that manifests on the collector node, using a negative feedback loop back to transistor bias condition(s) on one or more amplification stages.

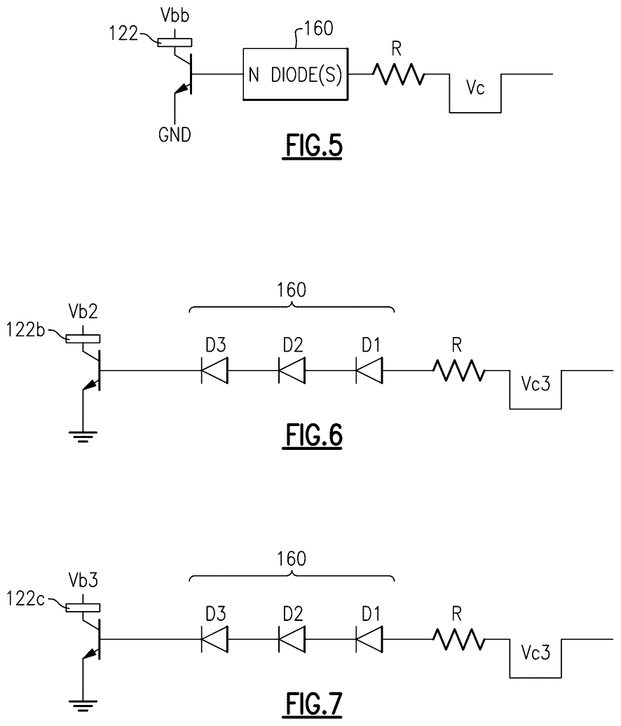

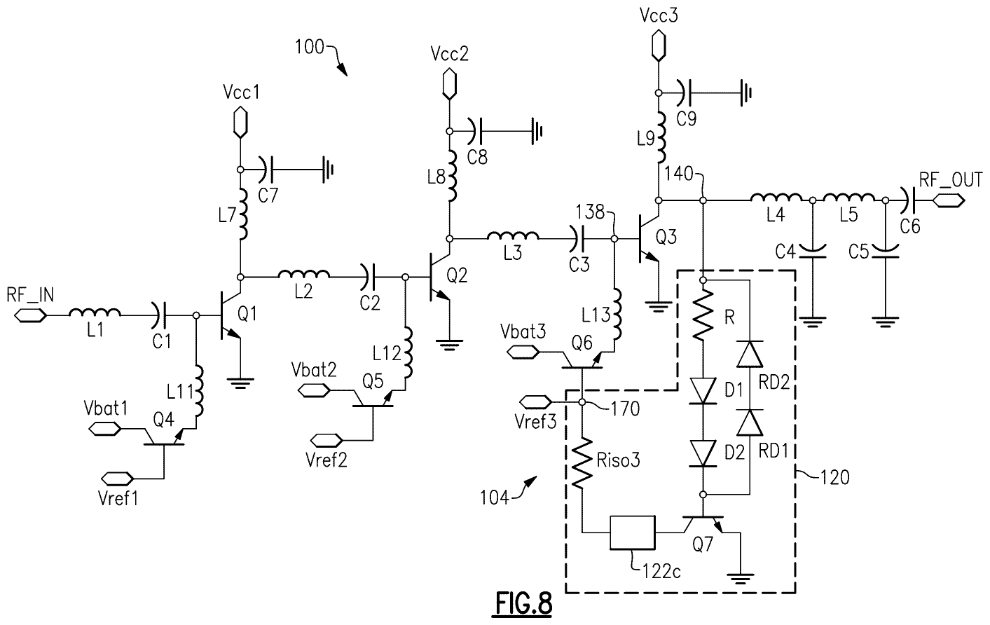

As described herein, an amplifying transistor for which Vbb is reduced may or may not be the same amplifying transistor at which peak voltage condition is being detected. FIG. 6 shows a more specific example of the peak voltage detection configuration of FIG. 5, where peak voltage (Vc3) is detected at the collector of the last stage (in a 3-stage example) and such voltage is routed to a sinking transistor (when the diodes 160 are turned ON) so as to reduce the base voltage Vb2 of the second stage, according to one embodiment of the present disclosure. Thereby, the base voltage Vb2 passes the attenuator 122b coupled to the bias circuit of the second stage, and its feedback is reduced. FIG. 7 shows another more specific example of the peak voltage detection configuration of FIG. 5, where peak voltage (Vc3) is detected at the collector of the last stage (in a 3-stage example) and such voltage is routed to a sinking transistor (when the diodes 160 are turned ON) so as to reduce the base voltage Vb3 of the same third stage, according to one embodiment of the present disclosure. Thereby, the base voltage Vb3 passes the attenuator 122c coupled to the bias circuit of the third stage, and its feedback is reduced. Examples of both of the configurations of FIGS. 6 and 7 are described herein in greater detail.

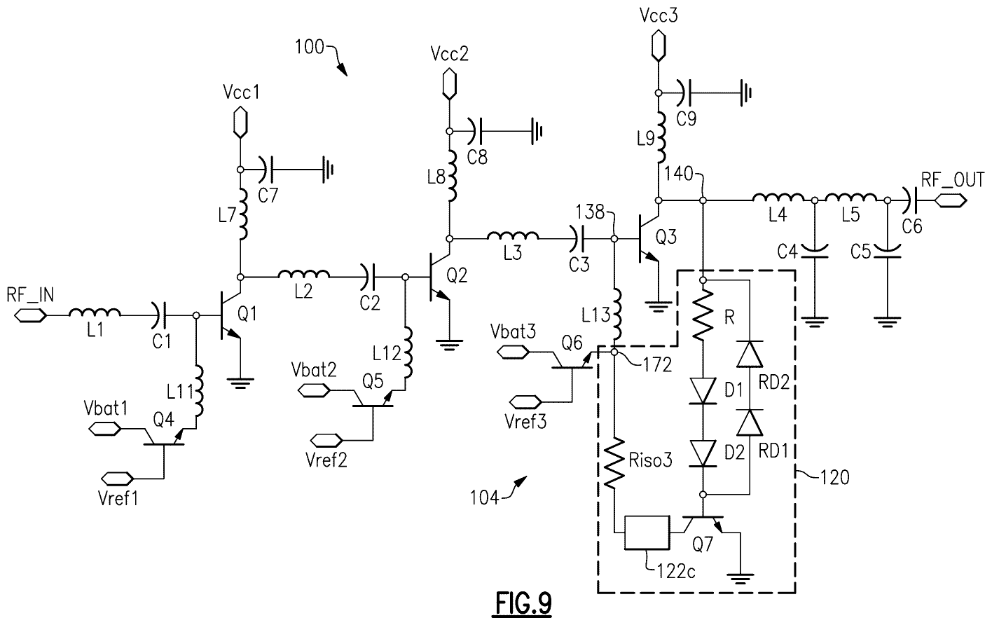

FIGS. 8-11 show examples where PVL circuits 104 are implemented in different manners in an example 3-stage PA system described herein in reference to FIG. 3, according to various embodiments of the present disclosure. Accordingly, details concerning the three stages and their respective supply circuits and bias circuits can be found herein in reference to FIG. 3.

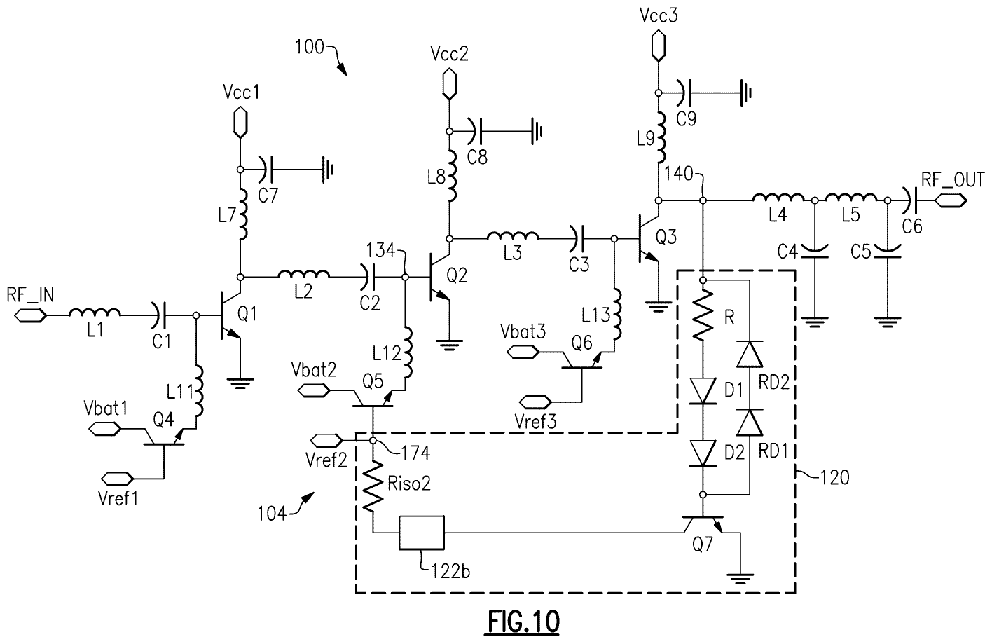

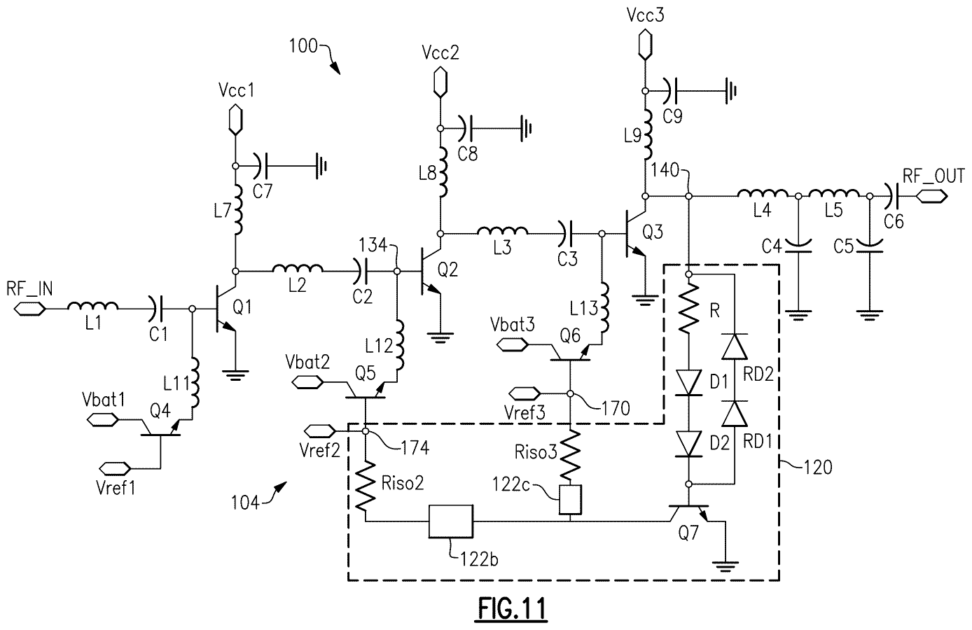

In each example of FIGS. 8 and 9, a PVL circuit 104 includes a detection circuit 120 that couples the collector node 140 of the third stage amplifier Q3 to the bias circuit for the same third stage amplifier Q3. In the example of FIG. 10, a PVL circuit 104 includes a detection circuit 120 that couples the collector node 140 of the third stage amplifier Q3 to the bias circuit for the second stage amplifier Q2. In the example of FIG. 11, a PVL circuit 104 includes a detection circuit 120 that couples the collector node 140 of the third stage amplifier Q3 to the bias circuit for the second stage amplifier Q2 as well as to the bias circuit for the third stage amplifier Q3.

In each of the four examples of FIGS. 8-11, the detection circuit 120 includes a series circuit having a resistance R and a group of diodes (depicted as D1 and D2), and a sinking transistor Q7. More particularly, the series circuit (R, D1 and D2) is shown to couple the collector node 140 and the base of the sinking transistor Q7. The group of diodes D1 and D2 is configured to protect against a positive voltage swing. Further, the detection circuit 120 includes a reverse diode circuit in parallel to the series circuit (R, D1 and D2). The reverse diode circuit comprises at least one reverse diode, preferably two reverse diodes RD1 and RD2, configured to protect the detection circuit 120 against a negative voltage swing. More particularly, the reverse diode circuit (RD1 and RD2) is shown to couple the collector node 140 and the base of the sinking transistor Q7. The emitter of Q7 is grounded, and the collector of Q7 is coupled to the respective bias circuit. It will be understood that the detection circuit 120 can include more or a fewer number of diodes. It will also be understood that the detection circuit 120 can include more or a fewer number of reverse diodes depending on the power of the RF signal. It will also be understood that the resistance R can be replaced with or be supplemented with one or more circuit elements such an inductance.

In the example of FIG. 8, the detection circuit 120 is shown to couple the collector node 140 of the third stage amplifier Q3 to the bias circuit of the same third stage amplifier Q3. More particularly, the collector of the sinking transistor Q7 is shown to be coupled to the reference voltage Vref3 node 170 of the emitter-follower bias circuit for the third stage amplifier Q3. Between the coupling of the node 170 and the sinking transistor Q7 an isolation resistor Riso3 and an attenuator 122c are integrated in series. More specifically, the isolation resistor Riso3 is coupled to the node 170 and the attenuator 122c, so arranged between the bias circuit of the third stage and the attenuator 122c. Accordingly, when the sinking transistor Q7 is turned ON through the diodes D1, D2 by a peak voltage condition or predetermined threshold, respectively, current can be diverted from the reference voltage Vref3 node 170 to ground through the isolation resistor Riso3, the attenuator 122c and the sinking transistor Q7, thereby reducing the voltage Vb3 provided to the base node 138 of the third stage amplifier Q3. A feedback of the passing current can be reduced by the attenuator 122c. The isolation resistor Riso3 is configured to isolate the bias circuit for the third stage amplifier Q3 when the base voltage Vb3 exceeds the predetermined threshold. That means when the base voltage Vb3 exceeds the predetermined threshold the detection circuit 120 is active or ON, respectively. In contrast to the resistance R which is in series with the diodes D1 and D2 and configured for the voltage limiting circuit in a situation when the detection circuit 120 is inactive.

In the example of FIG. 9, the detection circuit 120 is shown to couple the collector node 140 of the third stage amplifier Q3 to the bias circuit of the same third stage amplifier Q3. More particularly, the collector of the sinking transistor Q7 is shown to be coupled to the emitter node 172 of Q6 of the emitter-follower bias circuit for the third stage amplifier Q3. Between the coupling of the node 172 and the sinking transistor Q7 an isolation resistor Riso3 and an attenuator 122c are integrated in series. More specifically, the isolation resistor Riso3 is coupled to the node 172 and the attenuator 122c, so arranged between the bias circuit of the third stage and the attenuator 122c. Accordingly, when the sinking transistor Q7 is turned ON through the diodes D1, D2 by a peak voltage condition, current can be diverted from the emitter node 172 to ground through the isolation resistor Riso3, the attenuator 122c and the sinking transistor Q7, thereby reducing the voltage Vb3 provided to the base node 138 of the third stage amplifier Q3.

In the example of FIG. 10, the detection circuit 120 is shown to couple the collector node 140 of the third stage amplifier Q3 to the bias circuit of the second stage amplifier Q2. More particularly, the collector of the sinking transistor Q7 is shown to be coupled to the reference voltage Vref 2 node 174 of the emitter-follower bias circuit for the second stage amplifier Q2. Between the coupling of the node 174 and the sinking transistor Q7 an isolation resistor Riso2 and an attenuator 122b are integrated in series. More specifically, the isolation resistor Riso2 is coupled to the node 174 and the attenuator 122b, so arranged between the bias circuit of the second stage and the attenuator 122b. Accordingly, when the sinking transistor Q7 is turned ON through the diodes D1, D2 by a peak voltage condition, current can be diverted from the reference voltage Vref2 node 174 to ground through the isolation resistor Riso2, the attenuator 122b and the sinking transistor Q7, thereby reducing the voltage Vb2 provided to the base node 134 of the second stage amplifier Q2.

In the example of FIG. 11, the detection circuit 120 is shown to couple the collector node 140 of the third stage amplifier Q3 to the bias circuit of the second stage amplifier Q2 and to the bias circuit of the third stage amplifier Q3. More particularly, the collector of the sinking transistor Q7 is shown to be coupled to the reference voltage Vref 2 node 174 of the emitter-follower bias circuit for the second stage amplifier Q2. Between the coupling of the node 174 and the sinking transistor Q7 an isolation resistor Riso2 and an attenuator 122b are integrated in series. More specifically, the isolation resistor Riso2 is coupled to the node 174 and the attenuator 122b, so arranged between the bias circuit of the second stage and the attenuator 122b. Additionally, the collector of the sinking transistor Q7 is shown to be also coupled to the reference voltage Vref3 node 170 of the emitter-follower bias circuit for the third stage amplifier Q3. Between the coupling of the node 170 and the sinking transistor Q7 an isolation resistor Riso3 and an attenuator 122c are integrated in series. More specifically, the isolation resistor Riso3 is coupled to the node 170 and the attenuator 122c, so arranged between the bias circuit of the third stage and the attenuator 122c. Accordingly, when the sinking transistor Q7 is turned ON through the diodes D1, D2 by a peak voltage condition or predetermined threshold, respectively, current can be diverted from the reference voltage Vref2 node 174 to ground through the isolation resistor Riso2, the attenuator 122b and the sinking transistor Q7, thereby reducing the voltage Vb2 provided to the base node 134 of the second stage amplifier Q2. Further, current can also be diverted from the reference voltage Vref3 node 170 to ground through the isolation resistor Riso3, the attenuator 122c and the sinking transistor Q7, thereby reducing the voltage Vb3 provided to the base node 138 of the third stage amplifier Q3.

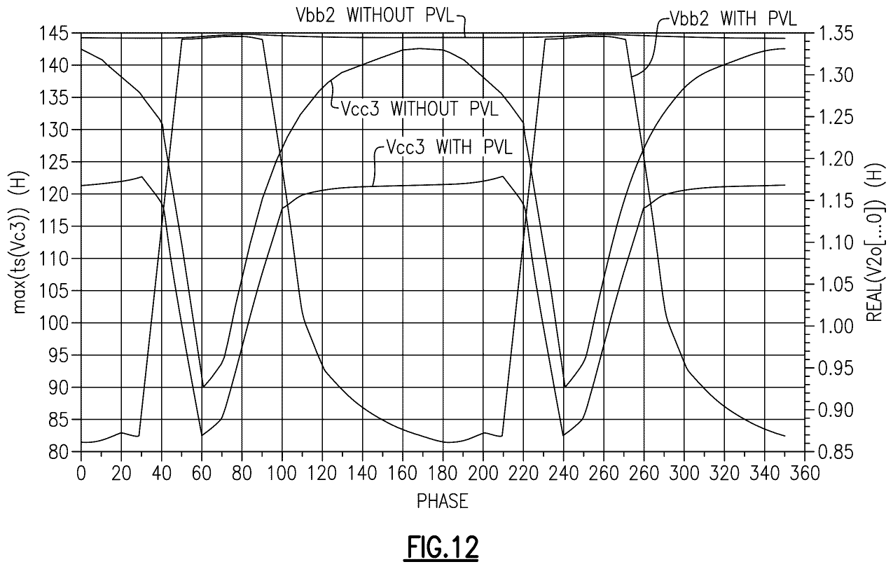

FIG. 12 shows an example of how a collector voltage Vcc3 can be advantageously limited by a PVL circuit having one or more features as described herein, according to one embodiment of the present disclosure. In FIG. 12, Vcc3 (with a vertical axis scale on the left) curves (with and without PVL functionality) are plotted as a function of phase. Also plotted are Vbb2 curves (with a vertical axis scale on the right) for the configurations with and without PVL functionality.

In the example of FIG. 12, Vbb2 remains approximately constant without the PVL functionality. Accordingly, Vcc3 is shown to reach relatively high peak values above 14 volts, thereby increasing the likelihood of breakdown.

With the PVL functionality, Vbb2 is shown to decrease when Vcc3 exceeds some predetermined threshold (e.g., about 12 volts). With such a decrease in Vbb2, Vcc3 is shown to be limited to a level slightly above the predetermined threshold. Accordingly, the limited Vcc3 level can decrease the likelihood of breakdown. It is further noted that when Vcc3 decreases below the predetermined threshold, Vbb2 is allowed to increase to its original level, thereby allowing normal operation.

In some embodiments, one or more features of the present disclosure can be utilized to limit the collector current instead of the collector voltage (e.g., Vcc3). However, as shown in the example of FIG. 12, the phase of Vcc3 with PVL is the same as or close to the phase of Vcc3 associated with normal operation. Accordingly, limiting the collector voltage can be preferable in many RF applications.

A PVL circuit having one or more features as described herein can be utilized as an effective ruggedness protection circuit. In some embodiments, such a desirable functionality can be realized without significantly degrading other performance parameters associated with a PA.

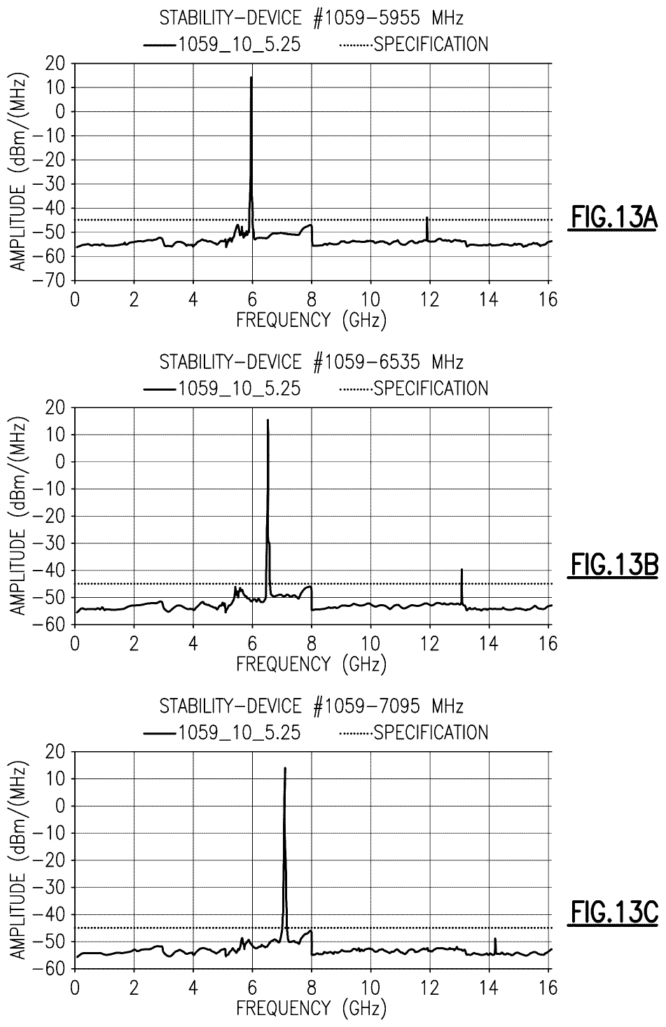

For example, FIGS. 13A, 13B and 13C show examples of performance with a PVL circuit operated at a temperature of −40° C., with a VSWR of 6:1 and with a supply voltage (Vcc) of 5.25V. More particularly, FIG. 13A shows a stability plot with a PVL circuit at a frequency of 5955 MHz, according to one embodiment of the present disclosure. FIG. 13B particularly shows a stability plot with a PVL circuit at a frequency of 6535 MHz, according to one embodiment of the present disclosure. FIG. 13C shows a stability plot with a PVL circuit at a frequency of 7095 MHz, according to one embodiment of the present disclosure. One can see that there substantially is not a spur activity since the RF signal is below the specification amplitude value (dotted line).

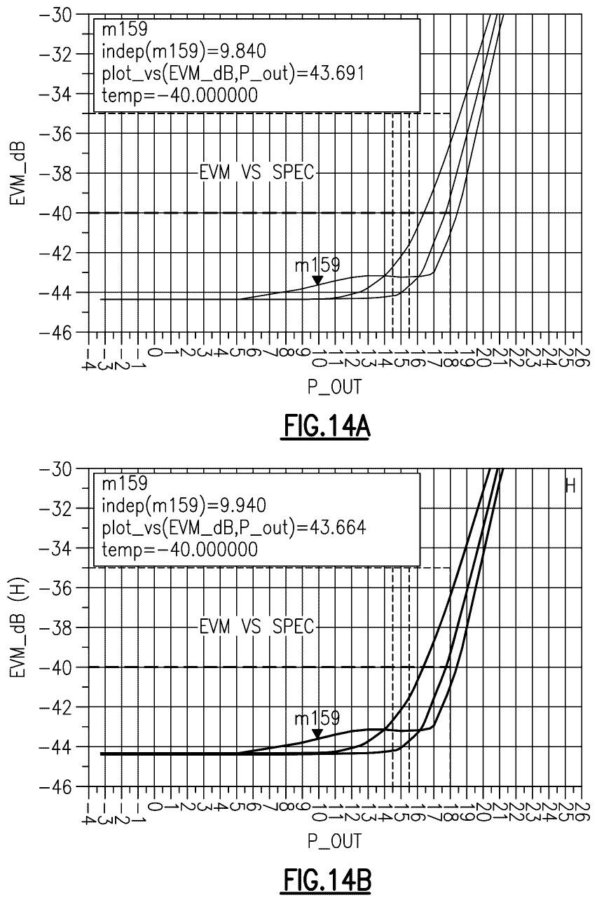

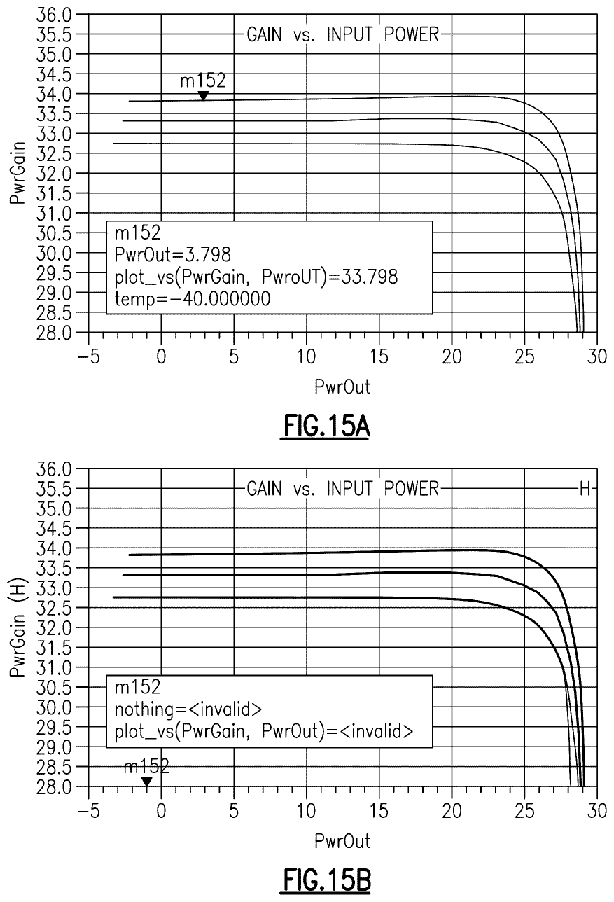

For example, FIGS. 14 and 15 show examples of performance with and without a PVL circuit. More particularly, FIG. 14A shows EVM performance plots without a PVL circuit, according to one embodiment of the present disclosure, and FIG. 14B shows EVM performance plots with a PVL circuit, according to one embodiment of the present disclosure. One can see that EVM performance is generally not degraded by the presence of the PVL circuit.

Similarly, FIG. 15A shows gain profiles without a PVL circuit, according to one embodiment of the present disclosure, and FIG. 15B shows gain profiles with a PVL circuit, according to one embodiment of the present disclosure. One can see that gain performance is generally not degraded by the presence of the PVL circuit.

In some embodiments, a PA having a PVL circuit as described herein can provide a number of advantageous features. Such features can include, for example, a smaller circuit while providing effective ruggedness protection, little or no hysteresis effect associated with operation of the PVL circuit, relatively quick response to high voltage excursions at collectors, and little or no degradation of the PA's normal operating characteristics.

In some embodiments, a PVL circuit as described herein can be implemented as a closed loop feedback system. Such a PVL circuit can be implemented in PAs that utilize different process technologies. For example, one or more features of the present disclosure can be implemented for NPN type amplifying transistors that are based on different process technologies as described herein.

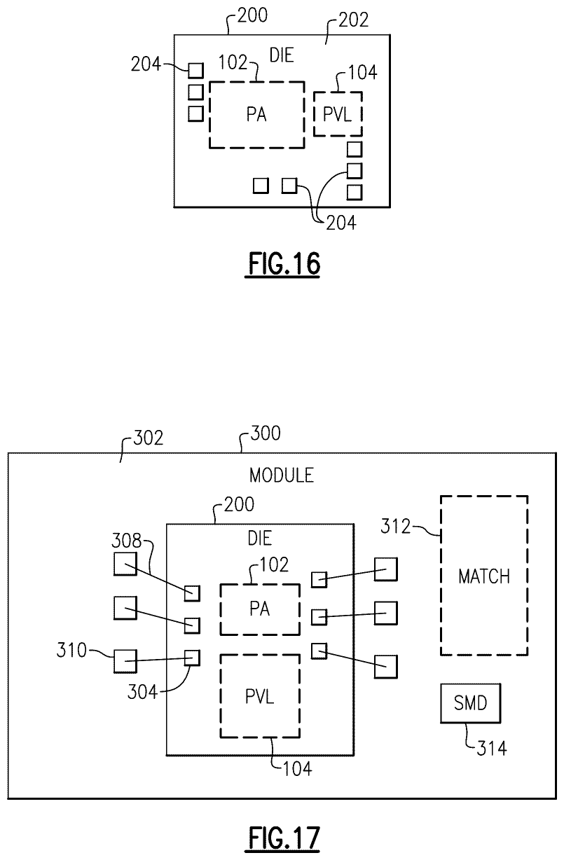

FIG. 16 depicts a die 200 that can include a PVL circuit 104 having one or more features as described herein, according to one embodiment of the present disclosure. The semiconductor die 200 can include a substrate 202. In some embodiments, a power amplifier (PA) circuit 102 (e.g., SiGe or GaAs devices) can also be implemented on the substrate 202. A plurality of connection pads 204 can also be formed on the substrate 202 to provide, for example, power and signals for the PA circuit 102.

In some implementations, one or more features described herein can be included in a module. FIG. 17 schematically depicts an example module 300 having a packaging substrate 302 that is configured to receive a plurality of components, according to one embodiment of the present disclosure. In some embodiments, such components can include a die 200 having one or more featured as described herein. For example, the die 200 can include a PA circuit 102 and a PVL circuit 104. A plurality of connection pads 304 can facilitate electrical connections such as wirebonds 308 to connection pads 310 on the substrate 302 to facilitate passing of various power and signals to and from the die 200.

In some embodiments, other components can be mounted on or formed on the packaging substrate 302. For example, one or more surface mount devices (SMDs) (314) and one or more matching networks (322) can be implemented. In some embodiments, the packaging substrate 302 can include a laminate substrate.

In some embodiments, the module 300 can also include one or more packaging structures to, for example, provide protection and facilitate easier handling of the module 300. Such a packaging structure can include an overmold formed over the packaging substrate 302 and dimensioned to substantially encapsulate the various circuits and components thereon.

It will be understood that although the module 300 is described in the context of wirebond-based electrical connections, one or more features of the present disclosure can also be implemented in other packaging configurations, including flip-chip configurations.

In some implementations, a device and/or a circuit having one or more features described herein can be included in an RF device such as a wireless device. Such a device and/or a circuit can be implemented directly in the wireless device, in a modular form as described herein, or in some combination thereof. In some embodiments, such a wireless device can include, for example, a cellular phone, a smart-phone, a hand-held wireless device with or without phone functionality, a wireless tablet, a wireless router, a wireless access point, a wireless base station, etc.

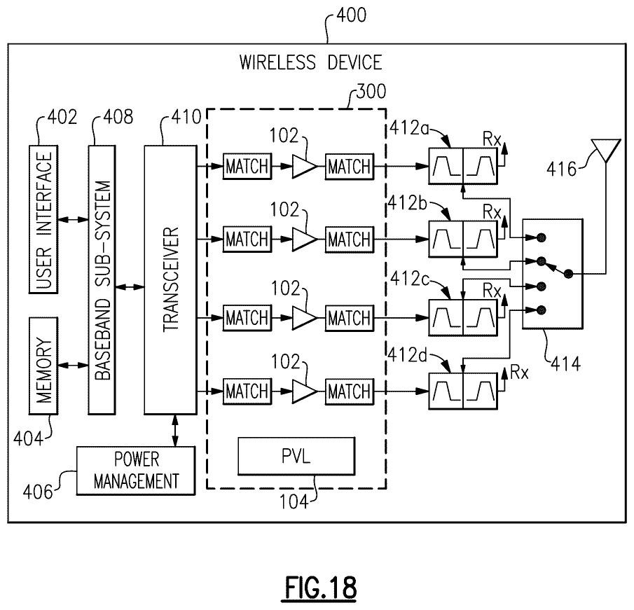

FIG. 18 schematically depicts an example wireless device 400 having one or more advantageous features described herein, according to one embodiment of the present disclosure. One or more PAs 102 as described herein can utilize one or more PVL circuits 104 as described herein. In embodiments where the PAs 102 and their PVL circuit(s) 104 are packaged into a module, such a module can be represented by a dashed box 300. In some embodiments, the module 300 can include at least some of input and output matching circuits.

The PAs 102 can receive their respective RF signals from a transceiver 410 that can be configured and operated in known manners to generate RF signals to be amplified and transmitted, and to process received signals. The transceiver 410 is shown to interact with a baseband sub-system 408 that is configured to provide conversion between data and/or voice signals suitable for a user and RF signals suitable for the transceiver 410. The transceiver 410 is also shown to be connected to a power management component 406 that is configured to manage power for the operation of the wireless device 400. Such power management can also control operations of the baseband sub-system 408 and the module 300.

The baseband sub-system 408 is shown to be connected to a user interface 402 to facilitate various input and output of voice and/or data provided to and received from the user. The baseband sub-system 408 can also be connected to a memory 404 that is configured to store data and/or instructions to facilitate the operation of the wireless device, and/or to provide storage of information for the user.

In the example wireless device 400, outputs of the PAs 102 are shown to be matched and routed to an antenna 416 via their respective duplexers 412a-412d and a band-selection switch 414. The band-selection switch 414 can be configured to allow selection of, for example, an operating band or an operating mode. In some embodiments, each duplexer 412 can allow transmit and receive operations to be performed simultaneously using a common antenna (e.g., 416). In FIG. 18, received signals are shown to be routed to “Rx” paths (not shown) that can include, for example, a low-noise amplifier (LNA). A number of other wireless device configurations can utilize one or more features described herein. For example, a wireless device does not need to be a multi-band device. In another example, a wireless device can include additional antennas such as diversity antenna, and additional connectivity features such as Wi-Fi, Bluetooth, and GPS.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “can,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

The above detailed description of embodiments of the invention is not intended to be exhaustive or to limit the invention to the precise form disclosed above. While its specific embodiments of and examples for the invention are described above for illustrative purposes, various equivalent modifications are possible within the scope of the invention, as those skilled in the relevant art will recognize. For example, while processes or blocks are presented in a given order, alternative embodiments may perform routine and may employ systems having blocks, in a different order, or some processes or blocks may be deleted, moved, added, subdivided, combined and/or modified. Each of these blocks may be implemented in a variety of different ways.

The teaching of the present invention provided herein can be applied to other systems, not necessarily the system described above. The elements and various embodiments described above can be combined to provide further embodiments.

While certain embodiments of the present invention have been described, these embodiments have been presented by way of example only, and are not intended to limit the scope of the disclosure. Indeed, the device and system described herein may be embodied in a variety of other forms. Furthermore, various omissions, substitutions and changes in the form of the system described herein may be made without departing from the spirit of the disclosure. The accompanying claims and the equivalents are intended to cover such forms or modifications as would fall within the scope of the disclosure.

What is claimed is:

1. A voltage limiting circuit for a power amplifier, comprising:
a diode circuit coupled to an output of an amplification stage of the power amplifier and configured to provide a conductive path from the output when an output voltage of the amplification stage exceeds a predetermined threshold;
a bias circuit configured to generate a bias voltage; and
a sink circuit including an attenuator, coupled to the diode circuit and the bias circuit, and configured to reduce the bias voltage when the output voltage exceeds the predetermined threshold to thereby limit the output voltage, the attenuator being configured to reduce a feedback of the output voltage routing through the sink circuit.

2. The voltage limiting circuit of claim 1 wherein the attenuator is configured to filter the output voltage.

3. The voltage limiting circuit of claim 2 wherein the attenuator includes a broadband filter.

4. The voltage limiting circuit of claim 2 wherein the attenuator is configured as a high pass filter or a low pass filter.

5. The voltage limiting circuit of claim 1 further comprising a reverse diode configured to protect the voltage limiting circuit against a negative voltage swing, the reverse diode being coupled in parallel to the diode circuit.

6. The voltage limiting circuit of claim 1 wherein the sink circuit further includes an isolation resistor in series with the attenuator, the isolation resistor configured to isolate the sink circuit from the bias circuit when the output voltage exceeds the predetermined threshold.

7. The voltage limiting circuit of claim 6 wherein the isolation resistor is coupled to the bias circuit and the attenuator.

8. A power amplifier comprising:
an input port configured to receive an input radio-frequency (RF) signal;
an output port configured to output an amplified RF signal;
one or more amplification stages implemented between the input port and the output port, the one or more amplification stages configured to amplify the input RF signal to yield the amplified RF signal;
one or more bias circuits, each bias circuit being configured to generate a bias voltage for each of the one or more amplification stages; and
a ruggedness protection circuit including a diode circuit coupled to an output of a selected one of the one or more amplification stages, the diode circuit being configured to provide a conductive path from the output when an output voltage exceeds a predetermined threshold, the ruggedness protection circuit further including a sink circuit coupled to the diode circuit and a selected bias circuit, the sink circuit being configured to reduce the bias voltage generated by the selected bias circuit when the output voltage exceeds the predetermined threshold to thereby limit the output voltage, the sink circuit comprising an attenuator, the attenuator configured to reduce a feedback of the output voltage routing through the sink circuit.

9. The power amplifier of claim 8 wherein the attenuator is configured to filter the output voltage.

10. The power amplifier of claim 9 wherein the attenuator includes a broadband filter.

11. The power amplifier of claim 9 wherein the attenuator is configured as a high pass filter or a low pass filter.

12. The power amplifier of claim 8 wherein the ruggedness protection circuit further includes a reverse diode configured to protect the voltage limiting circuit against a negative voltage swing, the reverse diode being coupled in parallel to the diode circuit.

13. The power amplifier of claim 8 wherein the sink circuit further includes an isolation resistor in series with the attenuator, the isolation resistor being configured to isolate from the bias circuit when the output voltage exceeds the predetermined threshold.

14. The power amplifier of claim 13 wherein the isolation resistor is coupled to the bias circuit and the attenuator.

15. The power amplifier of claim 8 wherein the one or more amplification stages each includes a driver stage and an output stage.

16. The power amplifier of claim 8 wherein the ruggedness protection circuit is configured to limit the output voltage to reduce likelihood of damage to the output stage without significantly reducing performance of the PA.

17. A wireless device comprising:
a transceiver configured to generate a radio-frequency (RF) signal;
a radio frequency (RF) module in communication with the transceiver, the RF module including a power amplifier, the power amplifier including one or more amplification stages configured to amplify the RF signal, the power amplifier further including a bias circuit for each of the one or more amplification stages, the power amplifier further including a ruggedness protection circuit including a diode circuit coupled to an output of a selected one of the one or more amplification stages, the diode circuit being configured to provide a conductive path from the output when an output voltage exceeds a predetermined threshold, the ruggedness protection circuit further including a sink circuit coupled to the diode circuit and a selected bias circuit, the sink circuit being configured to reduce a bias voltage provided by the selected bias circuit when the output voltage exceeds the predetermined threshold to thereby limit the output voltage, the sink circuit comprising an attenuator, the attenuator being configured to reduce a feedback of the output voltage routing through the sink circuit; and
an antenna in communication with the RF module, the antenna being configured to facilitate transmission of the amplified RF signal.

18. A method of operating a power amplifier, the method comprising:
detecting a condition where an output voltage of an amplification stage exceeds a predetermined threshold;
providing a conductive path from an output of the amplification stage upon detecting the condition;
activating a sink circuit coupled to the conductive path to reduce a bias voltage provided by a bias circuit; and
reducing a feedback of the output voltage routing through the sink circuit.

19. The method of claim 18 wherein reducing a feedback of the output voltage includes reducing the feedback of the output voltage using an attenuator included in the sink circuit.
